(19) United States
(12) Patent Application Publication
(10) Pub. No.: US 2026/0128104 A1
(43) Pub. Date: May 7, 2026

(54) MEMORY DEVICE AND MEMORY SYSTEM

(71) Applicant: MACRONIX INTERNATIONAL CO., LTD., HSINCHU (TW)

(72) Inventor: Po-Hao TSENG, Taichung City (TW)

(21) Appl. No.: 19/077,142

(22) Filed: Mar. 12, 2025

Related U.S. Application Data
(60) Provisional application No. 63/717,299, filed on Nov. 7, 2024.

(51) Int. Cl. G11C 16/26; G11C 16/08; G11C 16/24

(52) U.S. Cl. CPC G11C 16/26; G11C 16/08; G11C 16/24

(57) ABSTRACT

A memory device includes a memory string. The memory string includes a first and a second string portions. The first string portion stores stored filter bits, and compares input filter bits with the stored filter bits. The second string portion stores stored computing bits, and compares input computing bits with the stored computing bits. When the input filter bits is different from the stored filter bits, the string current signal has a first current level, when the input filter bits is equal to the stored filter bits, and the input computing bits has a first difference with the stored computing bits, the string current signal has a second current level, and when the input filter bits is equal to the stored filter bits, and the input computing bits has a second difference with the stored computing bits, the string current signal has a third current level.

### BACKGROUND

### Technical Field

The present disclosure relates to a memory technique. More particularly, the present disclosure relates to a memory device and a memory system.

### Description of Related Art

Existing in-memory searching (IMS) functions can compare input data and stored data to perform matching operations. However, the existing IMS functions consume relatively high chip power. Thus, techniques associated with the designing a memory device that can save the chip power and perform IMS functions are important issues in the field.

### SUMMARY

The present disclosure provides a memory device. The memory device includes a memory string configured to generate a string current signal. The memory string includes a first string portion and a second string portion. The first string portion configured to store at least one stored filter bit, and compare at least one input filter bit with the at least one stored filter bit. The second string portion coupled in series with the first string portion, and configured to store a plurality of stored computing bits, and compare a plurality of input computing bits with the plurality of stored computing bits. When an input value of the at least one input filter bit is different from a stored value of the at least one stored filter bit, the string current signal has a first current level, when the input value of the at least one input filter bit is equal to the stored value of the at least one stored filter bit, and an input value of the plurality of input computing bits has a first difference with a stored value of the plurality of stored computing bits, the string current signal has a second current level, and when the input value of the at least one input filter bit is equal to the stored value of the at least one stored filter bit, and the input value of the plurality of input computing bits has a second difference with the stored value of the plurality of stored computing bits, the string current signal has a third current level.

In some embodiments, each of the second current level and the third current level is larger than the first current level, and the second current level and the third current level are different from each other.

In some embodiments, the first difference is smaller than the second difference, and the second current level is larger than the third current level.

In some embodiments, when the input value of the at least one input filter bit is equal to the stored value of the at least one stored filter bit, and the input value of the plurality of input computing bits has a third difference with the stored value of the plurality of stored computing bits, the string current signal has a fourth current level, the third difference is larger than each of the first difference and the second difference, and the fourth current level is smaller than each of the second current level and the third current level.

In some embodiments, when the input value of the at least one input filter bit is equal to the stored value of the at least one stored filter bit, and the input value of the plurality of input computing bits has a fourth difference with the stored value of the plurality of stored computing bits, the string current signal has a fifth current level, the fourth difference is larger than the first difference and the second difference, and the fifth current level is smaller than the fourth current level, and is larger than the first current level.

In some embodiments, when the first string portion comprising a plurality of switch elements, when the store value of the at least one stored filter bit has a range, each of the plurality of switch elements has a first threshold voltage level.

In some embodiments, when the store value of the at least one stored filter bit has the range and the at least one input filter bit has a first input value, each of the plurality of switch elements is turned on, and when the store value of the at least one stored filter bit has the range and the at least one input filter bit has a second input value different from the first input value, each of the plurality of switch elements is turned on.

In some embodiments, the plurality of switch elements are configured to receive a plurality of word line signals, respectively, when the input value of the at least one input filter bit has the range, each of the plurality of word line signals has a first voltage level, and each of the plurality of switch elements is turned on.

The present disclosure provides a memory device. The memory device includes a memory string configured to generate a string current signal. The memory string includes a first string portion and a second string portion. The first string portion includes a plurality of first switch elements, and is configured to store at least one stored filter bit. The second string portion includes a plurality of second switch elements coupled in series with the plurality of first switch elements, and is configured to store a plurality of stored computing bits. The plurality of first switch elements are configured to respectively receive a plurality of first word line signals carrying at least one input filter bit. The plurality of second switch elements are configured to respectively receive a plurality of second word line signals carrying a plurality of input computing bits. When an input value of the at least one input filter bit is different from a stored value of the at least one stored filter bit, at least one of the plurality of first switch elements is turned off, when the input value of the at least one input filter bit is equal to the stored value of the at least one stored filter bit, and an input value of the plurality of input computing bits has a first difference with a stored value of the plurality of stored computing bits, the string current signal has a first current level, and when the input value of the at least one input filter bit is equal to the stored value of the at least one stored filter bit, and the input value of the plurality of input computing bits has a second difference with the stored value of the plurality of stored computing bits, the string current signal has a second current level.

In some embodiments, when the input value of the at least one input filter bit is equal to the stored value of the at least one stored filter bit, each of the plurality of first switch elements is turned on.

In some embodiments, the first difference is smaller than the second difference, and the first current level is larger than the second current level.

In some embodiments, the plurality of second switch elements include: a third switch element configured to have a first threshold voltage level when the plurality of stored computing bits has a first store value, and configured to have a second threshold voltage level larger than the first threshold voltage level when the plurality of stored computing bits has a second store value.

In some embodiments, the plurality of second switch elements further include: a fourth switch element configured to have the first threshold voltage level when the plurality of stored computing bits has the second store value, and configured to have the second threshold voltage level when the plurality of stored computing bits has a third store value, wherein the third store value is larger than each of the second store value and the first store value.

In some embodiments, the plurality of second switch elements further include: a fifth switch element configured to have the first threshold voltage level when the plurality of stored computing bits has the third store value, and configured to have the second threshold voltage level when the plurality of stored computing bits has a fourth store value, wherein the fourth store value is larger than the third store value.

In some embodiments, the plurality of second switch elements further include: a fifth switch element configured to have the second threshold voltage level when the plurality of stored computing bits has the first store value, configured to have the first threshold voltage level when the plurality of stored computing bits has the second store value, and configured to have the first threshold voltage level when the plurality of stored computing bits has the third store value.

In some embodiments, the plurality of second switch elements further include: a sixth switch element configured to have the second threshold voltage level when the plurality of stored computing bits has the first store value, configured to have the second threshold voltage level when the plurality of stored computing bits has the second store value, and configured to have the first threshold voltage level when the plurality of stored computing bits has the third store value.

The present disclosure provides a memory system. The memory system includes a plurality of memory strings configured to generate a plurality of bit line signals. The plurality of memory strings include a plurality of first memory strings and a plurality of second memory strings. The plurality of first memory strings are configured to compare a plurality of first stored data and a plurality of input data to generate a plurality of first string current signals, and sum the plurality of first string current signals to generate a first bit line signal. The plurality of second memory strings are configured to compare a plurality of second stored data and the plurality of input data to generate a plurality of second string current signals, and sum the plurality of second string current signals to generate a second bit line signal. In response to a store value of store filter bits stored in a third memory string of the plurality of first memory strings being different from an input value of input filter bits of a first input data of the plurality of input data, at least one switch element in the third memory string is turned off, and in response to a store value of store filter bits stored in a fourth memory string of the plurality of second memory strings being equal to the input value of the input filter bits of the first input data of the plurality of input data, when a difference between a store value of stored computing bits stored in the fourth memory string and an input value of input computing bits of the first input data is smaller, a current level of a third string current signal generated by the fourth memory string is larger.

In some embodiments, in response to a store value of store filter bits stored in a fifth memory string of the plurality of first memory strings being different from an input value of input filter bits of a second input data of the plurality of input data, at least one switch element in the fifth memory string is turned off.

In some embodiments, in response to a store value of store filter bits stored in a sixth memory string of the plurality of second memory strings being equal to the input value of the input filter bits of the second input data of the plurality of input data, when a difference between a store value of stored computing bits stored in the sixth memory string and an input value of input computing bits of the second input data is smaller, a current level of a fourth string current signal generated by the sixth memory string is larger.

In some embodiments, in response to a first difference being between the store value of the stored computing bits stored in the fourth memory string and the input value of the input computing bits of the first input data, the third string current signal has a first current level, in response to a second difference being between the store value of the stored computing bits stored in the sixth memory string and the input value of the input computing bits of the second input data, the fourth string current signal has a second current level, the first difference is larger than the second difference, and the first current level is smaller than the second current level.

It is to be understood that both the foregoing general description and the following detailed description are examples, and are intended to provide further explanation of the disclosure as claimed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic diagram of a part of a memory device, illustrated according to some embodiments of present disclosure.

FIG. 1B is a table of a hybrid encoding of the filter bits and the computing bits, illustrated according to some embodiments of present disclosure.

FIG. 1C to FIG. 1G are schematic diagrams of other conditions of the memory device, illustrated according to some embodiments of present disclosure.

FIG. 2A is a table of a hybrid encoding of the filter bits and the computing bits, illustrated according to some embodiments of present disclosure.

FIG. 2B to FIG. 2E are schematic diagrams of other conditions of the memory device, illustrated according to some embodiments of present disclosure.

FIG. 3A to FIG. 3C are schematic diagrams of the memory string, illustrated according to some embodiments of present disclosure.

FIG. 4 is a flowchart diagram of a method of generating the stored data, illustrated according to some embodiments of present disclosure.

FIG. 5A is a schematic diagram of a memory system illustrated according to some embodiments of present disclosure.

FIG. 5B is a schematic diagram of the memory device shown in FIG. 5A, illustrated according to some embodiments of present disclosure.

### DETAILED DESCRIPTION

In the present disclosure, when an element is referred to as “connected” or “coupled”, it may mean “electrically connected” or “electrically coupled”. “Connected” or “coupled” can also be used to indicate that two or more components operate or interact with each other. In addition, although the terms “first”, “second”, and the like are used in the present disclosure to describe different elements, the terms are used only to distinguish the elements or operations described in the same technical terms. The use of the term is not intended to be a limitation of the present disclosure.

Unless otherwise defined, all terms (including technical and scientific terms) used in the present disclosure have the same meaning as commonly understood by the ordinary skilled person to which the concept of the present invention belongs. It will be further understood that terms (such as those defined in commonly used dictionaries) should be interpreted as having a meaning consistent with its meaning in the related technology and/or the context of this specification and not it should be interpreted in an idealized or overly formal sense, unless it is clearly defined as such in this article.

The terms used in the present disclosure are only used for the purpose of describing specific embodiments and are not intended to limit the embodiments. As used in the present disclosure, the singular forms “a”, “one” and “the” are also intended to include plural forms, unless the context clearly indicates otherwise. It will be further understood that when used in this specification, the terms “comprises (comprising)” and/or “includes (including)” designate the existence of stated features, steps, operations, elements and/or components, but the existence or addition of one or more other features, steps, operations, elements, components, and/or groups thereof are not excluded.

Hereinafter multiple embodiments of the present disclosure will be disclosed with schema, as clearly stated, the details in many practices it will be explained in the following description. It should be appreciated, however, that the details in these practices is not applied to limit the present disclosure. Also, it is to say, in some embodiments of the present disclosure, the details in these practices are non-essential. In addition, for the sake of simplifying schema, some known usual structures and element in the drawings by a manner of simply illustrating for it.

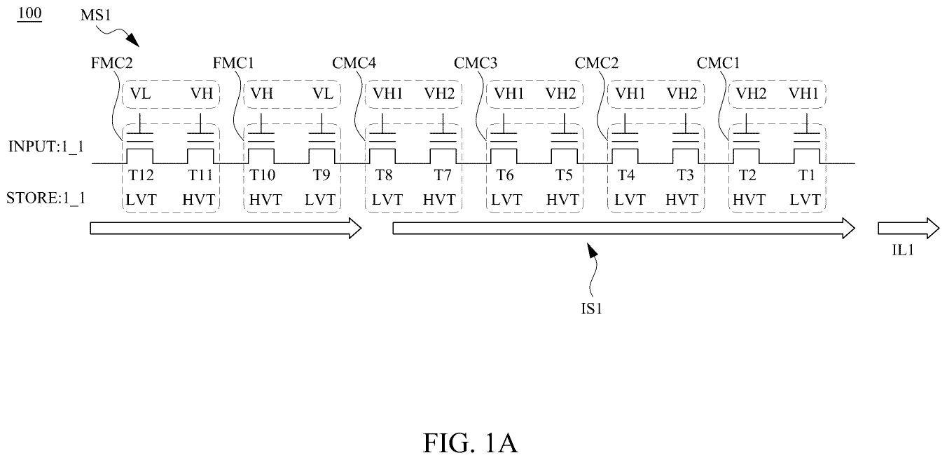

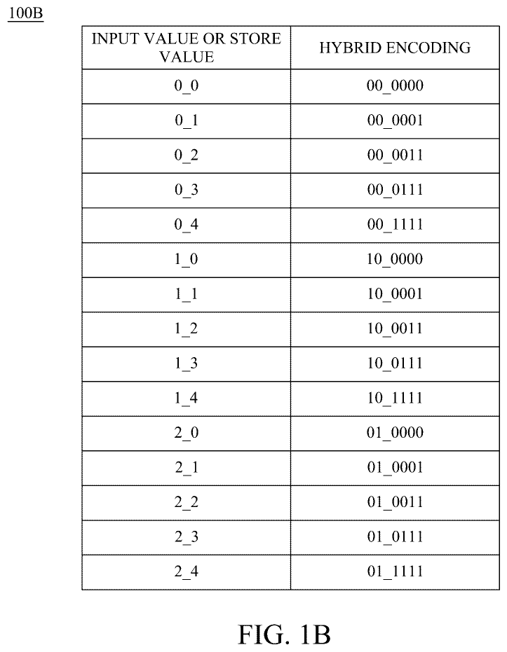

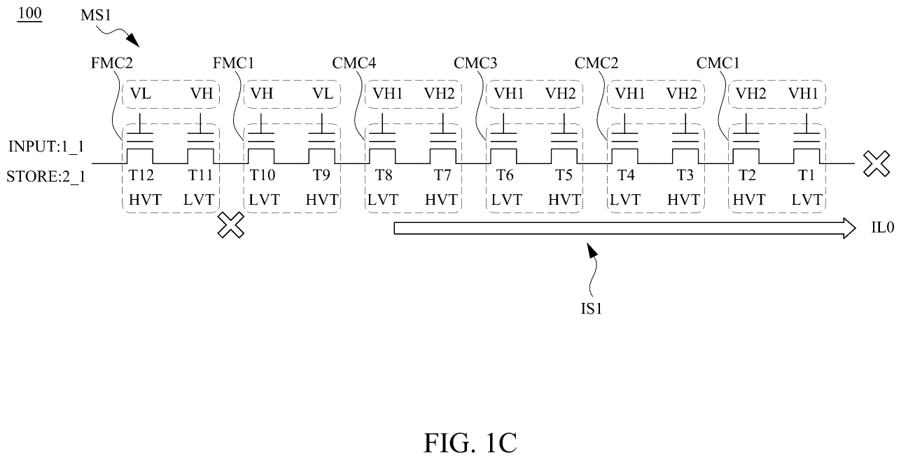

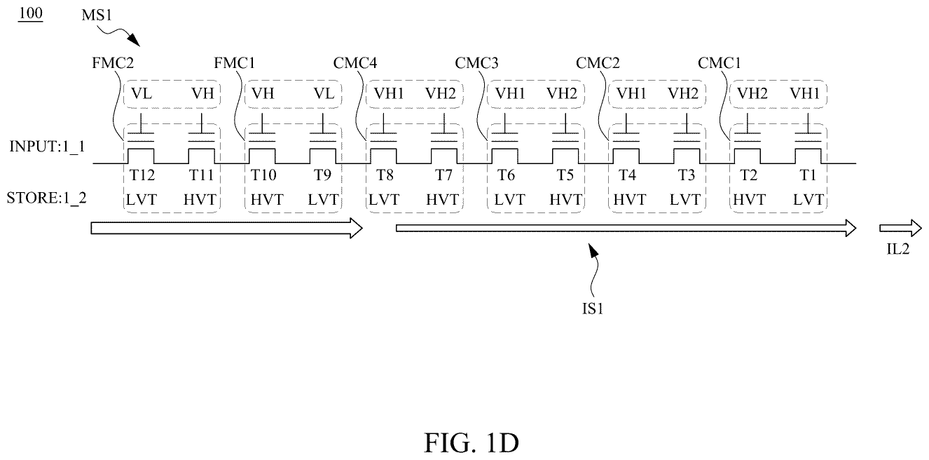

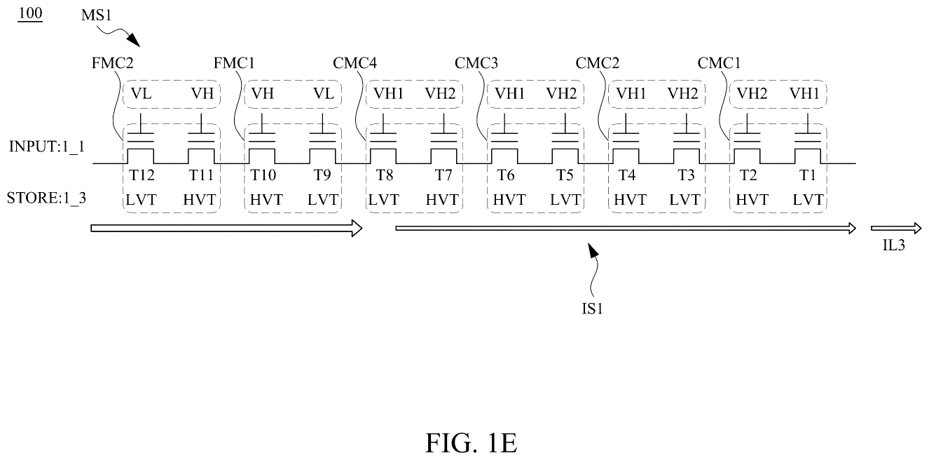

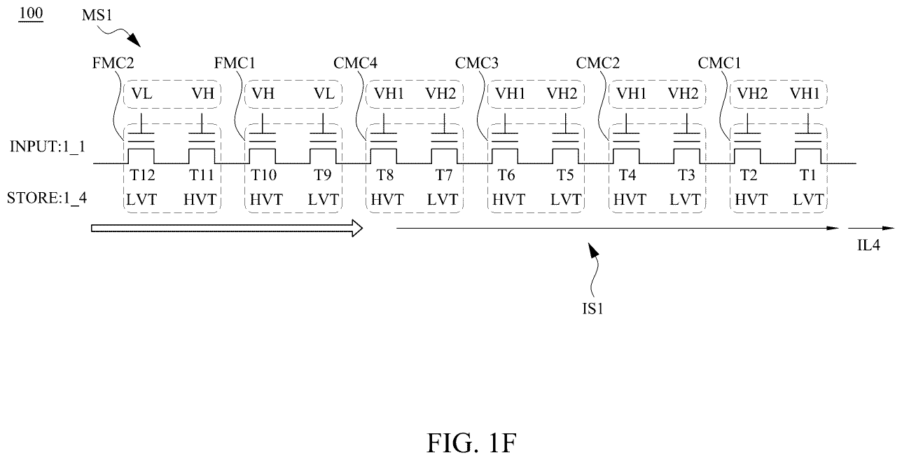

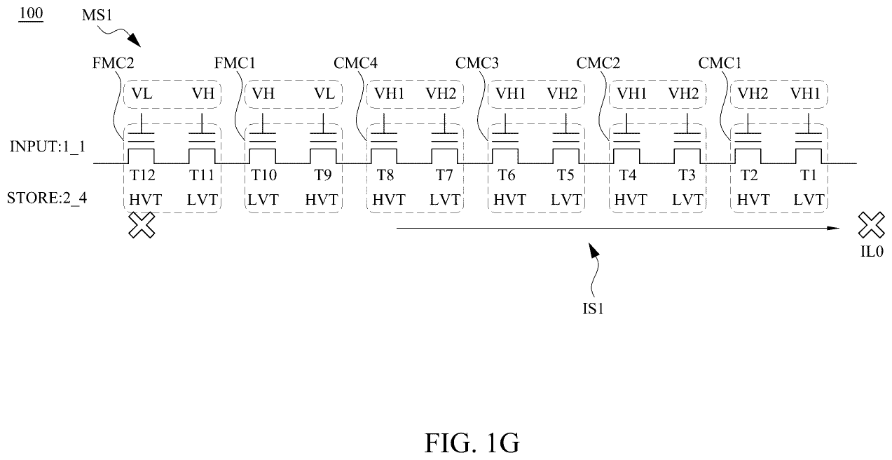

FIG. 1A is a schematic diagram of a part of a memory device 100, illustrated according to some embodiments of present disclosure. In some embodiments, the memory device 100 can be implemented by three-dimensional NAND memory array.

In some embodiments, the memory device 100 includes multiple memory strings, such as the memory string MS1 shown in FIG. 1A. The memory string MS1 is configured to store stored data SDT, and compare input data IDT and the stored data SDT to generate a string current signal IS1.

As shown in FIG. 1A, the memory string MS1 includes switch elements T1-T12. The switch elements T1-T12 are coupled in series with each other, and are arranged in order. However, the embodiments of present disclosure are not limited to this. In various embodiments, the memory string MS1 can includes various quantities of switch elements. Alternatively stated, 12 can be substituted by other positive integers.

In the embodiment shown in FIG. 1A, the switch elements T1 and T2 are configured to operate as a memory cell CMC1. The switch elements T3 and T4 are configured to operate as a memory cell CMC2. The switch elements T5 and T6 are configured to operate as a memory cell CMC3. The switch elements T7 and T8 are configured to operate as a memory cell CMC4. The switch elements T10 and T11 are configured to operate as a memory cell FMC1. The switch elements T11 and T12 are configured to operate as a memory cell FMC2.

The stored data includes stored computing bits SCB1-SCB4 and stored filter bits SFB1, SFB2. The memory cells CMC1-CMC4 are configured to store the stored computing bits SCB1-SCB4, respectively. The memory cells FMC1 and FMC2 are configured to store the stored filter bits SFB1 and SFB2, respectively.

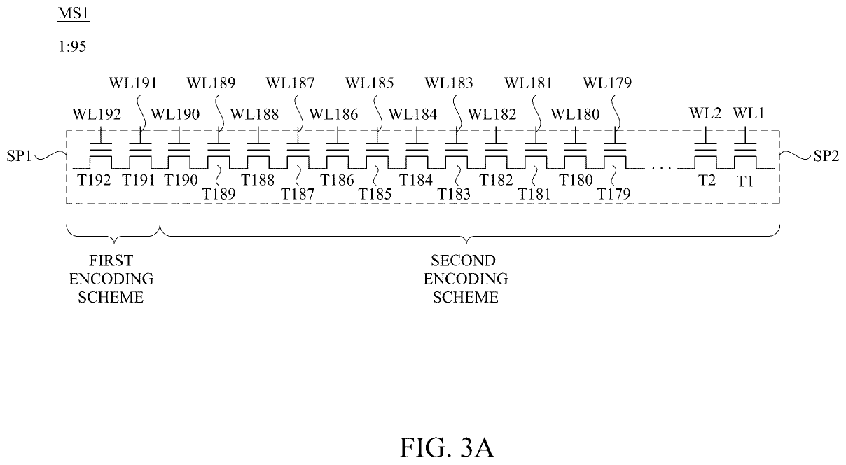

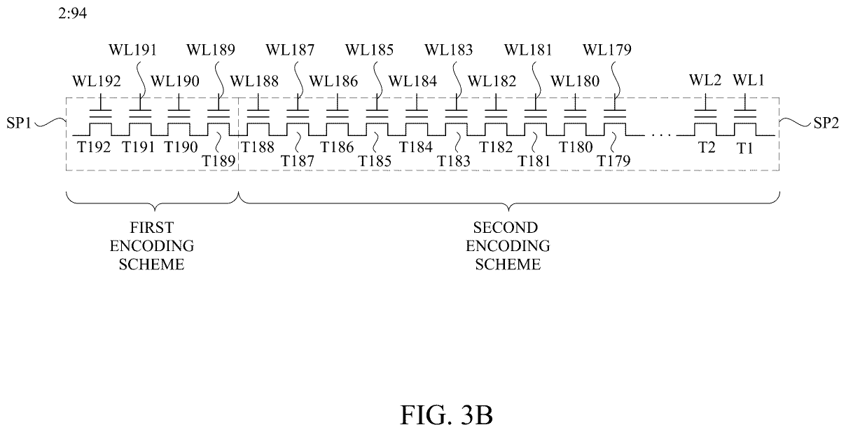

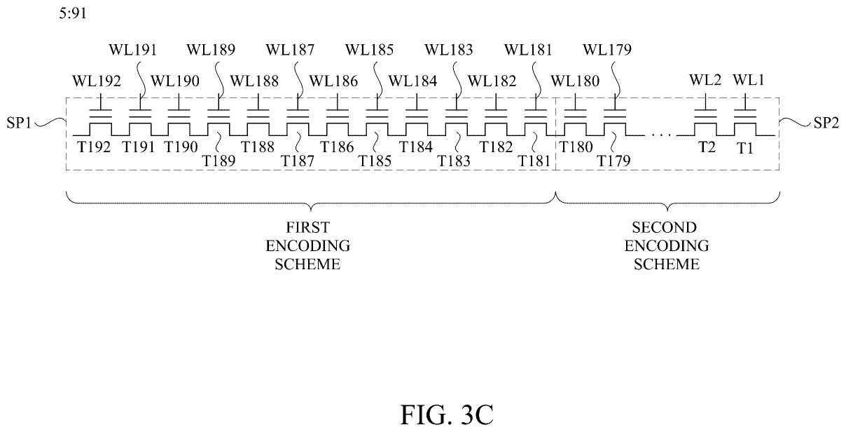

Alternatively stated, the memory string MS1 includes a first string portion and a second string portion, such as the string portions SP1 and SP2 shown in FIG. 3A to FIG. 3C. The first string portion is configured to store the stored filter bits, such as the stored filter bits SFB1 and SFB2. The second string portion is configured to store the stored computing bits, such as the stored computing bits SCB1-SCB4. In the embodiment shown in FIG. 1A, the first string portion includes the memory cells FMC1 and FMC2, and the second string portion includes the memory cells CMC1-CMC4.

In some embodiments, when a stored computing bit has a logic value 0, two switch elements in the corresponding memory cell have threshold voltage levels HVT and LVT, respectively. For example, when the stored computing bit SCB4 has the logic value 0, the switch elements T7 and T8 in the memory cell CMC4 have the threshold voltage levels HVT and LVT, respectively.

In some embodiments, the threshold voltage level HVT is larger than the threshold voltage level LVT. For example, the threshold voltage level LVT is smaller than 0 volt, and the threshold voltage level HVT is between 3 volts and 4 volts.

In contrast, when a stored computing bit has a logic value 1, two switch elements in the corresponding memory cell have the threshold voltage levels LVT and HVT, respectively. For example, when the stored computing bit SCB1 has the logic value 1, the switch elements T1 and T2 in the memory cell CMC1 have the threshold voltage levels LVT and HVT, respectively.

Similarly, when a stored filter bit has the logic value 0, two switch elements in the corresponding memory cell have the threshold voltage levels LVT and HVT, respectively. For example, when the stored filter bit SFB1 has the logic value 0, the switch elements T9 and T10 in the memory cell FM14 have the threshold voltage levels LVT and HVT, respectively.

In contrast, when a stored filter bit has the logic value 1, two switch elements in the corresponding memory cell have the threshold voltage levels HVT and LVT, respectively. For example, when the stored computing bit SCB1 has the logic value 1, the switch elements T11 and T12 in the memory cell FMC2 have the threshold voltage levels HVT and LVT, respectively.

On the other hand, control terminals of the switch elements T1-T12 are configured to receive word line signals WL1-WL12, respectively. The input data IDT includes input filter bits IFB1, IFB2 and input computing bits ICB1-ICB4. The word line signals WL1 and WL2 are configured to carry the input computing bit ICB1. The word line signals WL3 and WL4 are configured to carry the input computing bit ICB2. The word line signals WL5 and WL6 are configured to carry the input computing bit ICB3. The word line signals WL7 and WL8 are configured to carry the input computing bit ICB4. The word line signals WL9 and WL10 are configured to carry the input filter bit IFB1. The word line signals WL11 and WL12 are configured to carry the input filter bit IFB2.

In some embodiments, when an input computing bit has the logic value 0, corresponding word line signals have voltage levels VH2 and VH1, respectively. For example, when the input computing bit ICB2 has the logic value 0, the word line signals WL3 and WL4 have the voltage levels VH2 and VH1, respectively.

In contrast, when an input computing bit has the logic value 1, corresponding word line signals have the voltage levels VH1 and VH2, respectively. For example, when the input computing bit ICB1 has the logic value 1, the word line signals WL1 and WL2 have the voltage levels VH1 and VH2, respectively.

Similarly, when an input filter bit has the logic value 0, corresponding word line signals have voltage levels VL and VH, respectively. For example, when the input filter bit IFB1 has the logic value 0, the word line signals WL9 and WL10 have the voltage levels VL and VH, respectively.

In contrast, when an input filter bit has the logic value 1, corresponding word line signals have the voltage levels VH and VL, respectively. For example, when the input filter bit IFB2 has the logic value 1, the word line signals WL11 and WL12 have the voltage levels VH and VL, respectively.

In some embodiments, the voltage level VL is larger than the threshold voltage level LVT and is smaller than the threshold voltage level HVT. Correspondingly, when a word line signal has the voltage level VL and a corresponding switch element has the threshold voltage level LVT, the switch element is turned on. When a word line signal has the voltage level VH and a corresponding switch element has the threshold voltage level HVT, the switch element is turned off.

In some embodiments, each of the voltage levels VH, VH1 and VH2 is larger than the threshold voltage level HVT. Correspondingly, when a word line signal has the voltage levels VH, VH1 or VH2, a corresponding switch element is turned on. In some embodiments, the voltage level VH2 is larger than the voltage level VH1. For example, the voltage level VH2 is between 7 volts and 8 volts, and the voltage level VH1 is approximately equal to 4 volts. In some embodiments, the voltage level VH is between the voltage levels VH1 and VH2, such as 6 volts.

In some embodiments, when a word line signal has the voltage level VH2 and a corresponding switch element has the threshold voltage level HVT, a resistance of the switch element is smaller, such that a current passing through the switch element is larger. In contrast, when a word line signal has the voltage level VH1 and a corresponding switch element has the threshold voltage level HVT, a resistance of the switch element is larger, such that a current passing through the switch element is smaller.

FIG. 1B is a table 100B of a hybrid encoding of the filter bits and the computing bits, illustrated according to some embodiments of present disclosure. In the embodiment shown in FIG. 1B, the left side of the underline corresponds to the filter bits of one-hot encoding, and the right side of the underline corresponds to the computing bits of thermometer encoding. The filter bits described above correspond to the input filter bits and the stored filter bits, and the computing bits described above correspond to the input computing bits and the stored computing bits.

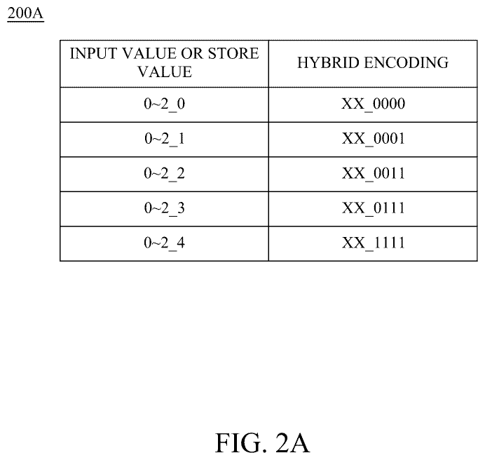

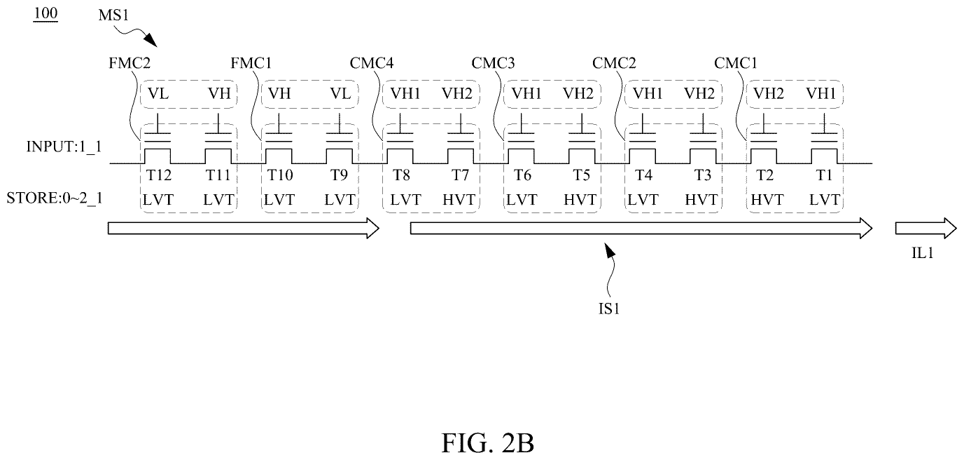

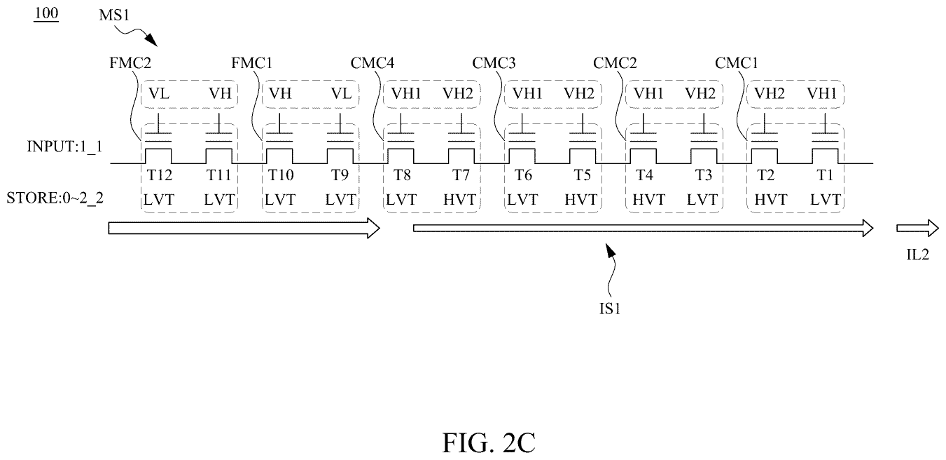

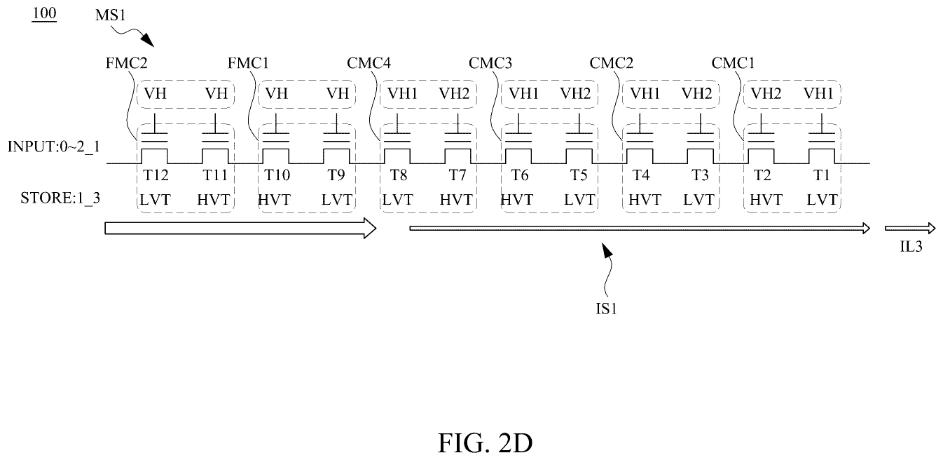

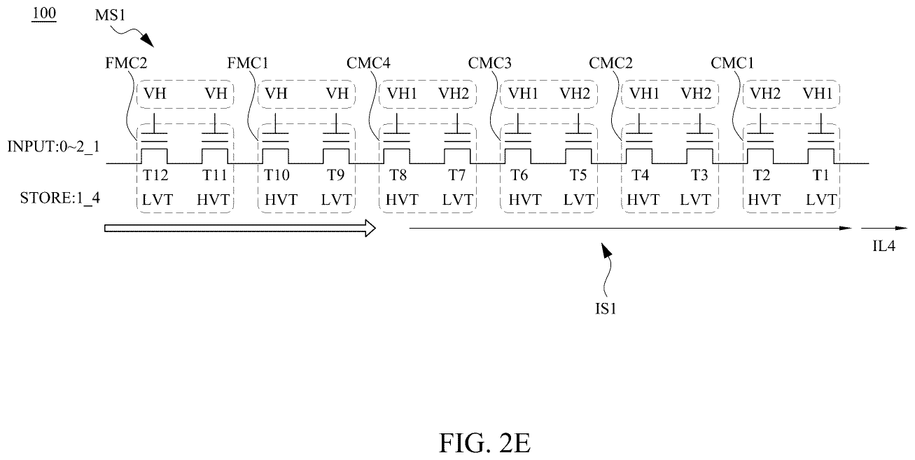

In some embodiments, the processor can perform calculations to the logic values of the stored filter bits and the stored computing bits to generate corresponding store values, and perform calculations to the logic values of the input filter bits and the input computing bits to generate corresponding input values, by a feature extractor in an artificial intelligence (AI),. For example, the processor can transform the logic values into the store values and the input values according to the tables 100B and 200A shown in FIG. 1B and FIG. 2A.

As shown in FIG. 1B, when each of the stored computing bits SCB1-SCB4 has the logic value 0, the stored computing bits SCB1-SCB4 have a store value 0. When the stored computing bits SCB1-SCB4 have the logic values 1, 0, 0, 0, respectively, the stored computing bits SCB1-SCB4 have a store value 1. When the stored computing bits SCB1-SCB4 have the logic values 1, 1, 0, 0, respectively, the stored computing bits SCB1-SCB4 have a store value 2. When the stored computing bits SCB1-SCB4 have the logic values 1, 1, 1, 0, respectively, the stored computing bits SCB1-SCB4 have a store value 3. When each of the stored computing bits SCB1-SCB4 has the logic value 1, the stored computing bits SCB1-SCB4 have a store value 4.

Similarly, when each of the input computing bits ICB1-ICB4 has the logic value 0, the input computing bits ICB1-ICB4 have an input value 0. When the input computing bits ICB1-ICB4 have the logic values 1, 0, 0, 0, respectively, the input computing bits ICB1-ICB4 have an input value 1. When the input computing bits ICB1-ICB4 have the logic values 1, 1, 0, 0, respectively, the input computing bits ICB1-ICB4 have an input value 2. When the input computing bits ICB1-ICB4 have the logic values 1, 1, 1, 0, respectively, the input computing bits ICB1-ICB4 have an input value 3. When each of the input computing bits ICB1-ICB4 has the logic value 1, the input computing bits ICB1-ICB4 have an input value 4.

On the other hand, when each of the stored filter bits SFB1 and SFB2 has the logic value 0, the stored filter bits SFB1 and SFB2 have the store value 0. When the stored filter bits SFB1 and SFB2 have the logic values 0 and 1, respectively, the stored filter bits SFB1 and SFB2 have the store value 1. When the stored filter bits SFB1 and SFB2 have the logic values 1 and 0, respectively, the stored filter bits SFB1 and SFB2 have the store value 2.

Similarly, when each of the input filter bits IFB1 and IFB2 has the logic value 0, the input filter bits IFB1 and IFB2 have the input value 0. When the input filter bits IFB1 and IFB2 have the logic values 0 and 1, respectively, the input filter bits IFB1 and IFB2 have the input value 1. When the input filter bits IFB1 and IFB2 have the logic values 1 and 0, respectively, the input filter bits IFB1 and IFB2 have the input value 2.

In the embodiment shown in FIG. 1B, the filter bits can have values of 0-2, and the stored bits can have values of 0-4. However, the embodiments of present disclosure are not limited to this. In various embodiments, the filter bits can have values of 0-n, and the stored bits can have values of 0-m. In which n and m are positive integers.

Referring to FIG. 1A again, in the embodiment shown in FIG. 1A, the input filter bits IFB1 and IFB2 have the input value 1, such that the word line signals WL9-WL12 have the voltage levels VL, VH, VH and VL, respectively. The stored filter bits SFB1 and SFB2 have the store value 1, such that the switch elements T9-T12 have the threshold voltage levels LVT, HVT, HVT and LVT, respectively. Correspondingly, each of the switch elements T9-T12 is turned on.

On the other hand, the input computing bits ICB1-ICB4 have the input value 1, such that each of the word line signals WL1, WL4, WL6 and WL8 has the voltage level VH1, and each of the word line signals WL2, WL3, WL5 and WL7 has the voltage level VH2. The stored computing bits SCB1-SCB4 have the store value 1, such that each of the switch elements T1, T4, T6 and T8 has the threshold voltage level LVT, and each of the switch elements T2, T3, T5 and T7 has the threshold voltage level HVT. At this moment, the input value 1 of the input computing bits ICB1-ICB4 and the store value 1 of the stored computing bits SCB1-SCB4 have a difference 0. Correspondingly, the string current signal IS1 has a current level IL1.

FIG. 1C is a schematic diagram of another condition of the memory device 100, illustrated according to some embodiments of present disclosure. In the embodiment shown in FIG. 1C, the input filter bits IFB1 and IFB2 have the input value 1, such that the word line signals WL9-WL12 have the voltage levels VL, VH, VH and VL, respectively. The stored filter bits SFB1 and SFB2 have the store value 2, such that the switch elements T9-T12 have the threshold voltage levels HVT, LVT, HVT and LVT, respectively. Correspondingly, each of the switch elements T9 and T12 are turned off, such that the string current signal IS1 has a current level IL0. In some embodiments, the current level IL0 is a zero current level.

Alternatively stated, when the input value of the input filter bits IFB1 and IFB2 is different from the store value of the stored filter bits SFB1 and SFB2, the current level IL0 of the string current signal IS1 is independent from the input value of the input computing bits ICB1-ICB4 and the store value of the stored computing bits SCB1-SCB4.

In some approaches, a memory string is not separated into two string portions corresponding to filtering and computing, such that when comparison results are mismatch, the memory string still generates a mismatch current. As a result, a requirement of chip power is higher.

Compared to above approaches, in some embodiments of present disclosure, when the input value of the input filter bits is different from the store value of the stored filter bits, the string current signal IS1 has the zero current level. As a result, by reducing the mismatch current, the chip power can be saved.

FIG. 1D is a schematic diagram of another condition of the memory device 100, illustrated according to some embodiments of present disclosure. In the embodiment shown in FIG. 1D, the input filter bits IFB1 and IFB2 have the input value 1, and the stored filter bits SFB1 and SFB2 also have the store value 1, such that each of the switch elements T9-T12 is turned on.

On the other hand, the input computing bits ICB1-ICB4 have the input value 1. The stored computing bits SCB1-SCB4 have the store value 2, such that each of the switch elements T1, T3, T6 and T8 has the threshold voltage level LVT, and each of the switch elements T2, T4, T5 and T7 has the threshold voltage level HVT. At this moment, the input value 1 of the input computing bits ICB1-ICB4 and the store value 2 of the stored computing bits SCB1-SCB4 have a difference 1. Correspondingly, the string current signal IS1 has a current level IL2. The current level IL2 is smaller than the current level IL1.

FIG. 1E is a schematic diagram of another condition of the memory device 100, illustrated according to some embodiments of present disclosure. In the embodiment shown in FIG. 1E, the input filter bits IFB1 and IFB2 have the input value 1, and the stored filter bits SFB1 and SFB2 also have the store value 1, such that each of the switch elements T9-T12 is turned on.

On the other hand, the input computing bits ICB1-ICB4 have the input value 1. The stored computing bits SCB1-SCB4 have the store value 3, such that each of the switch elements T1, T3, T5 and T8 has the threshold voltage level LVT, and each of the switch elements T2, T4, T6 and T7 has the threshold voltage level HVT. At this moment, the input value 1 of the input computing bits ICB1-ICB4 and the store value 3 of the stored computing bits SCB1-SCB4 have a difference 2. Correspondingly, the string current signal IS1 has a current level IL3. The current level IL3 is smaller than the current level IL2.

FIG. 1F is a schematic diagram of another condition of the memory device 100, illustrated according to some embodiments of present disclosure. In the embodiment shown in FIG. 1F, the input filter bits IFB1 and IFB2 have the input value 1, and the stored filter bits SFB1 and SFB2 also have the store value 1, such that each of the switch elements T9-T12 is turned on.

On the other hand, the input computing bits ICB1-ICB4 have the input value 1. The stored computing bits SCB1-SCB4 have the store value 4, such that each of the switch elements T1, T3, T5 and T7 has the threshold voltage level LVT, and each of the switch elements T2, T4, T6 and T8 has the threshold voltage level HVT. At this moment, the input value 1 of the input computing bits ICB1-ICB4 and the store value 4 of the stored computing bits SCB1-SCB4 have a difference 3. Correspondingly, the string current signal IS1 has a current level IL4. The current level IL4 is smaller than the current level IL3.

FIG. 1G is a schematic diagram of another condition of the memory device 100, illustrated according to some embodiments of present disclosure. In the embodiment shown in FIG. 1G, the input filter bits IFB1 and IFB2 have the input value 1, such that the word line signals WL9-WL12 have voltage levels VL, VH, VH and VL, respectively. The stored filter bits SFB1 and SFB2 have the store value 2, such that the switch elements T9-T12 have threshold voltage levels HVT, LVT, LVT and HVT, respectively. Correspondingly, each of the switch elements T9 and T12 are turned off, such that the string current signal IS1 has the current level IL0. The current level IL0 is smaller than the current level IL4.

On the other hand, the input computing bits ICB1-ICB4 have the input value 1, and the stored computing bits SCB1-SCB4 have the store value 4. However, due to the switch elements T9 and T12 being turned off, a difference between the input computing bits and the stored computing bits does not affect the string current signal IS1.

In summary, when the input value of the input filter bits is equal to the store value of the stored filter bits, in response to the difference between the input computing bits and the stored computing bits being larger, the current level of the string current signal IS1 is smaller, and in response to the difference between the input computing bits and the stored computing bits being smaller, the current level of the string current signal IS1 is larger. Alternatively stated, when the current level of the string current signal IS1 is larger, a similarity between the input computing bits and the stored computing bits is higher. When the current level of the string current signal IS1 is smaller, the similarity between the input computing bits and the stored computing bits is lower.

When the input value of the input filter bits is different from the store value of the stored filter bits, the string current signal IS1 has the current level IL0, and does not be changed according to the difference between the input computing bits and the stored computing bits.

FIG. 2A is a table 200A of a hybrid encoding of the filter bits and the computing bits, illustrated according to some embodiments of present disclosure. Referring to FIG. 2A and FIG. 1B, the table 200A is an alternative embodiment of the table 100B. Therefore, some descriptions are not repeated for brevity.

Compared to the table 100B, in the embodiment shown in the table 200A, the filter bits can have a logic value X. The logic value X represents a wildcard logic value or a “don't care” logic value. In some embodiments, the wildcard logic value is indicated as an arbitrary logic value during input, and the “don't care”logic value is indicated as an arbitrary logic value during stored.

As shown in the table 200A, when each of the stored filter bits SFB1 and SFB2 has the logic value X, the stored filter bits SFB1 and SFB2 have a range of the store values 0-2. Alternatively stated, the stored filter bits SFB1 and SFB2 correspond to the store values 0, 1 and 2, simultaneously.

In some embodiments, when a stored filter bit has the logic value X, each of two switch elements in the memory cell has the threshold voltage level LVT. For example, when the stored filter bit SFB1 has the logic value X, each of the switch elements T9 and T10 has the threshold voltage level LVT.

Similarly, when each of the input filter bits IFB1 and IFB2 has the logic value X, the input filter bits IFB1 and IFB2 have a range of the input values 0-2. Alternatively stated, the input filter bits IFB1 and IFB2 correspond to the input values 0, 1 and 2, simultaneously.

In some embodiments, when an input filter bit has the logic value X, each of two corresponding word line signals has the voltage level VH. For example, when the input filter bit IFB1 has the logic value X, each of the word line signals WL9 and WL10 has the voltage level VH.

FIG. 2B is a schematic diagram of another condition of the memory device 100, illustrated according to some embodiments of present disclosure. In the embodiment shown in FIG. 2B, the input filter bits IFB1 and IFB2 have the input value 1, such that the word line signals WL9-WL12 have the voltage levels VL, VH, VH and VL, respectively. The stored filter bits SFB1 and SFB2 have the range of the store values 0-2, such that each of the switch elements T9-T12 has the threshold voltage level LVT. Correspondingly, each of the switch elements T9-T12 is turned on.

On the other hand, the input computing bits ICB1-ICB4 have the input value 1, and the stored computing bits SCB1-SCB4 also have the store value 1. Alternatively stated, the input value 1 of the input computing bits ICB1-ICB4 and the store value 4 of the stored computing bits SCB1-SCB4 have the difference 0, such that the string current signal IS1 has the current level IL1.

FIG. 2C is a schematic diagram of another condition of the memory device 100, illustrated according to some embodiments of present disclosure. In the embodiment shown in FIG. 2C, the input filter bits IFB1 and IFB2 have the input value 2, such that the word line signals WL9-WL12 have the voltage levels VH, VL, VL and VH, respectively. The stored filter bits SFB1 and SFB2 have the range of the store values 0-2, such that each of the switch elements T9-T12 has the threshold voltage level LVT. Correspondingly, each of the switch elements T9-T12 is turned on.

On the other hand, the input computing bits ICB1-ICB4 have the input value 1, and the stored computing bits SCB1-SCB4 have the store value 2. Alternatively stated, the input value 1 of the input computing bits ICB1-ICB4 and the store value 4 of the stored computing bits SCB1-SCB4 have the difference 1, such that the string current signal IS1 has the current level IL2.

FIG. 2D is a schematic diagram of another condition of the memory device 100, illustrated according to some embodiments of present disclosure. In the embodiment shown in FIG. 2D, the input filter bits IFB1 and IFB2 have the range of the input values 0-2, such that each of the word line signals WL9-WL12 has the voltage level VH. The stored filter bits SFB1 and SFB2 have the store value 1, such that the switch elements T9-T12 have the threshold voltage levels LVT, HVT, HVT and LVT, respectively. Correspondingly, each of the switch elements T9-T12 is turned on.

On the other hand, the input computing bits ICB1-ICB4 have the input value 1, and the stored computing bits SCB1-SCB4 have the store value 3. Alternatively stated, the input value 1 of the input computing bits ICB1-ICB4 and the store value 3 of the stored computing bits SCB1-SCB4 have the difference 2, such that the string current signal IS1 has the current level IL3.

FIG. 2E is a schematic diagram of another condition of the memory device 100, illustrated according to some embodiments of present disclosure. In the embodiment shown in FIG. 2E, the input filter bits IFB1 and IFB2 have the range of the input values 0-2, and the stored filter bits SFB1 and SFB2 have the store value 1, such that each of the switch elements T9-T12 is turned on.

On the other hand, the input computing bits ICB1-ICB4 have the input value 1, and the stored computing bits SCB1-SCB4 have the store value 4. Alternatively stated, the input value 1 of the input computing bits ICB1-ICB4 and the store value 4 of the stored computing bits SCB1-SCB4 have the difference 3, such that the string current signal IS1 has the current level IL4.

FIG. 3A is a schematic diagram of the memory string MS1, illustrated according to some embodiments of present disclosure. In the embodiment shown in FIG. 3A, the memory string MS1 includes memory elements T1-T192. The memory elements T1-T192 are coupled in series with each other and are arranged in order. Control terminals of the memory elements T1-T192 are configured to receive word line signals WL1-WL192, respectively. However, the embodiments of present disclosure are not limited to this. In various embodiments, the memory string MS1 can includes various quantities of switch elements. Alternatively stated, 192 can be substituted by other positive integers.

In some embodiments, two adjacent switch elements are configured to operate as one memory cell. Correspondingly, the memory elements T1-T192 can be operate as 96 memory cells.

As shown in FIG. 3A, the memory string MS1 includes string portions SP1 and SP2. The string portions SP1 and SP2 are coupled in series with each other. In some embodiments, the string portion SP1 has an encoding scheme of exact matching, and configured for the filtering function. The string portion SP2 has an encoding scheme of approximate matching, and configured for the computing function. In some embodiments, the encoding scheme of the string portion SP1 can be implemented by the one-hot encoding, and the encoding scheme of the string portion SP2 can be implemented by the thermometer encoding. However, the embodiments of present disclosure are not limited to this. In various embodiments, the string portion SP1 can be implemented by other encoding schemes of exact matching, and the string portion SP2 can be implemented by other encoding schemes of approximate matching.

In the embodiment shown in FIG. 3A, the string portion SP1 includes switch elements T191 and T192, and the string portion SP2 includes switch elements T1-T190. Alternatively stated, the string portion SP1 includes 1 memory cell, and the string portion SP2 includes 95 memory cells.

FIG. 3B is a schematic diagram of the memory string MS1, illustrated according to some embodiments of present disclosure. Referring to FIG. 3B and FIG. 3A, the memory string MS1 shown in FIG. 3B is an alternative embodiment of the memory string MS1 shown in FIG. 3A. Therefore, some descriptions are not repeated for brevity.

In the embodiment shown in FIG. 3B, the string portion SP1 includes switch elements T189-T192, and the string portion SP2 includes switch elements T1-T188. Alternatively stated, the string portion SP1 includes 2 memory cells, and the string portion SP2 includes 94 memory cells.

FIG. 3C is a schematic diagram of the memory string MS1, illustrated according to some embodiments of present disclosure. Referring to FIG. 3C and FIG. 3A, the memory string MS1 shown in FIG. 3C is an alternative embodiment of the memory string MS1 shown in FIG. 3A. Therefore, some descriptions are not repeated for brevity.

In the embodiment shown in FIG. 3B, the string portion SP1 includes switch elements T181-T192, and the string portion SP2 includes switch elements T1-T180. Alternatively stated, the string portion SP1 includes 5 memory cells, and the string portion SP2 includes 91 memory cells.

In summary, the string portions SP1 and SP2 can include various quantities of memory cells. Specifically, the string portion SP1 can includes X memory cells configured to perform exact matching. The string portion SP2 can includes Y memory cells configured to perform approximate matching. It is noted that X and Y are positive integers. In various embodiments, X can be smaller than, larger than or equal to Y.

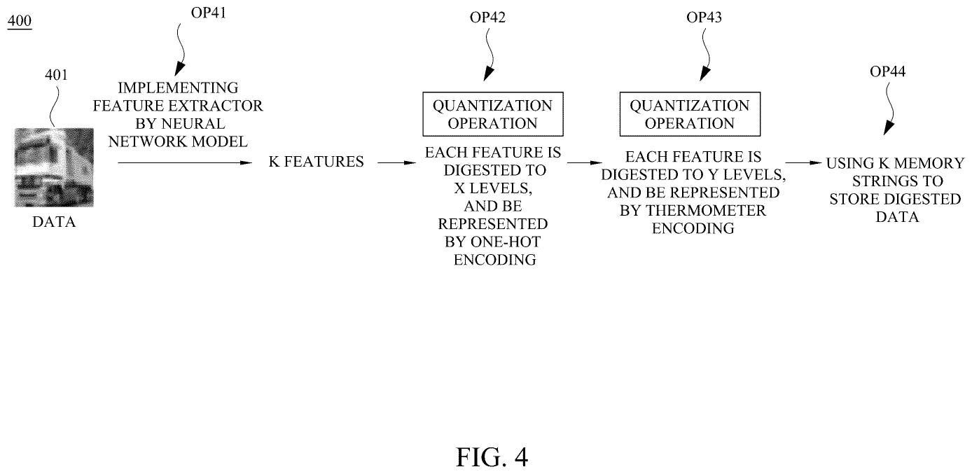

FIG. 4 is a flowchart diagram of a method 400 of generating the stored data, illustrated according to some embodiments of present disclosure. As shown in FIG. 4, the method 400 includes operations OP41-OP44. In some embodiments, the stored data SDT described above can be generated by the method 400.

During the operation OP41, a feature extractor extracts the data 401 into K features, in which K is a positive integer. In some embodiments, the feature extractor can be implemented by a neural network (NN) model.

In the embodiment shown in FIG. 4, the data 401 is image data. However, the embodiments of present disclosure are not limited to this. In various embodiments, the data 401 can be implemented by various types of data, such as audio data or text data.

During the operation OP42, a quantization operation is performed to the K features, to digest each feature of the K features into X levels, and represented by the one-hot encoding.

During the operation OP43, a quantization operation is performed to the K features, to digest each feature of the K features into Y levels, and represented by the thermometer encoding.

During the operation OP44, K memory strings are used to store the digested data 401.

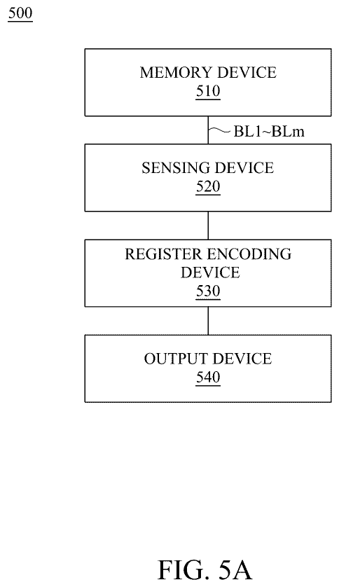

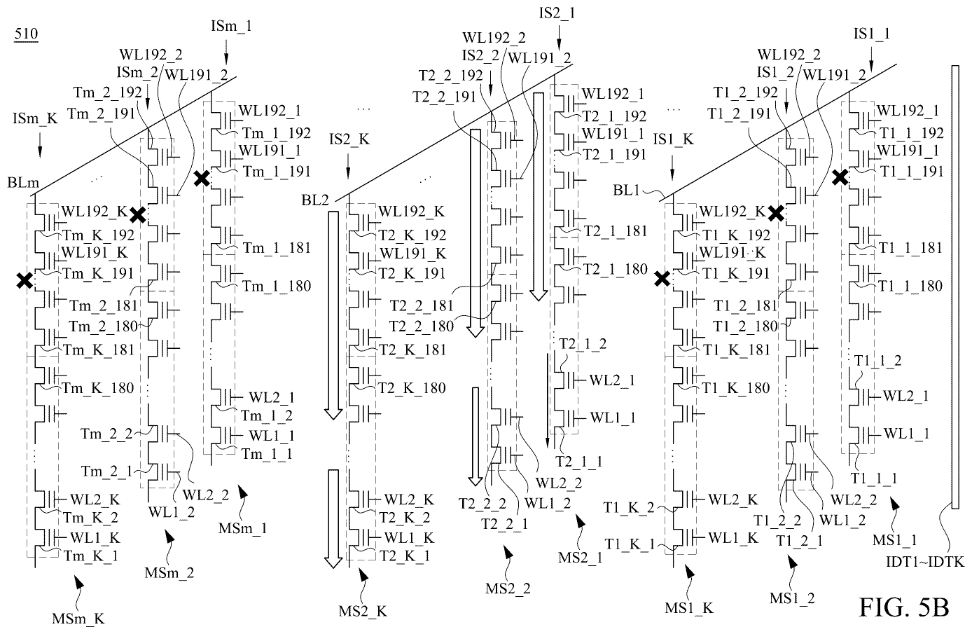

FIG. 5A is a schematic diagram of a memory system 500 illustrated according to some embodiments of present disclosure. As shown in FIG. 5A, the memory system 500 includes a memory device 510, a sensing device 520, a register encoding device 530 and an output device 540. In various embodiments, the memory device 510 can be implemented by three-dimensional NAND memory array. Referring to FIG. 1A and FIG. 5A, the memory device 510 is an alternative embodiment of the memory device 100. Therefore, for brevity, some descriptions are not repeated.

In some embodiments, the memory device 510 is configured to generate bit line signals BL1-BLm, in which m is a positive integer. The sensing device 520 can include a page buffer and a sensing amplifier, and configured to sense corresponding searching results of the bit line signals BL1-BLm. The register encoding device 530 can includes cache registers and priority encoders. The output device 540 is configured to output the matching results of the memory device 510.

In some embodiments, the process performed by the register encoding device 530 to the bit line signals includes logic processes of AND logic, OR logic or counting, and also may include combining processes of the three logic processes described above. Referring to FIG. 1A to FIG. 5A, the register encoding device 530 can receive sense results from the memory device 100 and/or 510, and controls sequencing (whether serial or parallel) and combines sense results to produce overall search results as the matching results outputted from the output device 540.

In some embodiments, the register encoding device 530 is further configured to perform priority encoding to the corresponding searching results of the bit line signals BL1-BLm. For example, the register encoding device 530 collectively processes the corresponding searching results of the bit line signals BL1-BLm, and preferentially select an address of a bit line signal corresponding to the best searching result (that is, the input value of the input data and the store value the stored data are closest to each other).

FIG. 5B is a schematic diagram of the memory device 510 shown in FIG. 5A, illustrated according to some embodiments of present disclosure. As shown in FIG. 5B, the memory device 510 includes multiple memory strings MS1_1-MS1_K, MS2_1-MS2_K, . . . , MSm_1-MSm_K. Referring to FIG. 1A to FIG. 5B, a configuration of each of the memory strings MS1_1-MS1_K, MS2_1-MS2_K, . . . , MSm_1-MSm_K is similar with the configuration of the memory strings MS1. Therefore, some descriptions are not repeated for brevity.

In some embodiments, the memory strings MS1_1-MS1_K are coupled in parallel with each other and configured to generate the bit line signal BL1. The memory strings MS2_1-MS2_K are coupled in parallel with each other and configured to generate the bit line signal BL2, and so on. The memory strings MSm_1-MSm_K are coupled in parallel with each other and configured to generate the bit line signal BLm.

In the embodiment shown in FIG. 5B, each of the memory strings MS1_1-MS1_K, MS2_1-MS2_K, . . . , MSm_1-MSm_K includes 192 switch elements coupled in series with each other. For example, the memory string MS1_1 includes switch elements T1_1_1-T1_1_192 coupled in series with each other. The memory string MS1_2 includes switch elements T1_2_1-T1_2_192 coupled in series with each other, and so on. The memory string MS1_K includes switch elements T1_K_1-T1_K_192 coupled in series with each other.

Similarly, the memory string MS2_1 includes switch elements T2_1_1-T2_1_192 coupled in series with each other. The memory string MS2_2 includes switch elements T2_2_1-T2_2_192 coupled in series with each other, and so on. The memory string MS2_K includes switch elements T2_K_1-T2_K_192 coupled in series with each other.

Similarly, the memory string MSm_1 includes switch elements Tm_1_1-Tm_1_192 coupled in series with each other. The memory string MSm_2 includes switch elements Tm_2_1-Tm_2_192 coupled in series with each other, and so on. The memory string MSm_K includes switch elements Tm_K_1-Tm_K_192 coupled in series with each other.

However, the embodiments of present disclosure are not limited to this. In various embodiments, the memory strings in the memory device 510 can includes various quantities of switch elements. Alternatively stated, 192 can be substituted by other positive integers.

As shown in FIG. 5B, each of control terminals of the switch elements T1_1_1-Tm_1_1 is configured to receive a word line signal WL1_1. Each of control terminals of the switch elements T1_1_2-Tm_1_2 is configured to receive a word line signal WL2_1, and so on. Each of control terminals of the switch elements T1_1_192-Tm_1_192 is configured to receive a word line signal WL192_1.

Similarly, each of control terminals of the switch elements T1_2_1-Tm_2_1 is configured to receive a word line signal WL1_2. Each of control terminals of the switch elements T1_2_2-Tm_2_2 is configured to receive a word line signal WL2_2, and so on. Each of control terminals of the switch elements T1_2_192-Tm_2_192 is configured to receive a word line signal WL192_2, and so on. Each of control terminals of the switch elements T1_K_1-Tm_K_1 is configured to receive a word line signal WL1_K. Each of control terminals of the switch elements T1_K_2-Tm_K_2 is configured to receive a word line signal WL2_K, and so on. Each of control terminals of the switch elements T1_K_192-Tm_K_192 is configured to receive a word line signal WL192_K.

In some embodiments, the memory strings MS1_1-MS1_K are configured to store stored data SDT1_1-SDT1_K, respectively. The memory strings MS2_1-MS2_K are configured to store stored data SDT2_1-SDT2_K, respectively, and so on. The memory strings MSm_1-MSm_K are configured to store stored data SDTm_1-SDTm_K, respectively. In some embodiments, the stored data SDT1_1-SDT1_K, SDT2_1-SDT2_K, . . . , SDTm_1-SDTm_K can be implemented by stored feature data.

On the other hand, the word line signals WL1_1-WL192_1 are configured to carry input data IDT1. The word line signals WL1_2-WL192_2 are configured to carry input data IDT2, and so on. The word line signals WL1_K-WL192_K are configured to carry input data IDTK. In some embodiments, the stored data input data IDT1-IDTK can be implemented by input feature data.

During the search operation, the memory string MS1_1 is configured to compare the stored data SDT1_1 and the input data IDT1, to generate a string current signal IS1_1. The memory string MS1_2 is configured to compare the stored data SDT1_2 and the input data IDT2, to generate a string current signal IS1_2, and so on. The memory string MS1_K is configured to compare the stored data SDT1_K and the input data IDTK, to generate a string current signal IS1_K.

Similarly, the memory string MS2_1 is configured to compare the stored data SDT2_1 and the input data IDT1, to generate a string current signal IS2_1. The memory string MS2_2 is configured to compare the stored data SDT2_2 and the input data IDT2, to generate a string current signal IS2_2, and so on. The memory string MS2_K is configured to compare the stored data SDT2_K and the input data IDTK, to generate a string current signal IS2_K, and so on. The memory string MSm_1 is configured to compare the stored data SDTm_1 and the input data IDT1, to generate a string current signal ISm_1. The memory string MSm_2 is configured to compare the stored data SDTm_2 and the input data IDT2, to generate a string current signal ISm_2, and so on. The memory string MSm_K is configured to compare the stored data SDTm_K and the input data IDTK, to generate a string current signal ISm_K.

In some embodiments, the memory strings MS1_1-MS1_K are configured to sum the string current signals IS1_1-IS1_K, to generate the bit line signal BL1. The memory strings MS2_1-MS2_K are configured to sum the string current signals IS2_1-IS2_K, to generate the bit line signal BL2, and so on. The memory strings MSm_1-MSm_K are configured to sum the string current signals ISm_1-ISm_K, to generate the bit line signal BLm.

Alternatively stated, a current level of the bit line signal BL1 is equal to a summation of current levels of the string current signals IS1_1-IS1_K. A current level of the bit line signal BL2 is equal to a summation of current levels of the string current signals IS2_1-IS2_K, and so on. A current level of the bit line signal BLm is equal to a summation of current levels of the string current signals ISm_1-ISm_K.

In some embodiments, each of the memory strings MS1_1-MS1_K, MS2_1-MS2_K, . . . , MSm_1-MSm_K includes a first string portion with filtering function and a second string portion with computing function. The first string portion is configured to store the stored filter bits, and the second string portion is configured to store the stored computing bit.

In the embodiment shown in FIG. 5B, the first string portion includes 12 switch elements, and the second string portion includes 180 switch elements. For example, the first string portion of the memory string MS1_1 includes switch elements T1_1_181-T1_1_192, and the second string portion of the memory string MS1_1 includes switch elements T1_1_1-T1_1_180.

During the search operation, the first string portion compares the stored filter bits and the input filter bits. When the store value of the stored filter bits is different from the input value of the input filter bits, the corresponding string current signal has the current level IL0 (that is, the zero current level). As a result, the filtering function reduces the total energy of the search operation.

For example, in the embodiment shown in FIG. 5B, each of store values of the stored filter bits of the first string portions of the memory strings MS1_1 and MSm_1 is different from an input value of the input filter bits of the input data IDT1, such that at least one switch element is turned off in each of the first string portions of the memory strings MS1_1 and MSm_1. Correspondingly, each of the string current signals IS1_1 and ISm_1 has the current level IL0.

Similarly, each of store values of the stored filter bits of the first string portions of the memory strings MS1_2 and MSm_2 is different from an input value of the input filter bits of the input data IDT2, such that at least one switch element is turned off in each of the first string portions of the memory strings MS1_2 and MSm_2. Correspondingly, each of the string current signals IS1_2 and ISm_2 has the current level IL0.

Similarly, each of store values of the stored filter bits of the first string portions of the memory strings MS1_K and MSm_K is different from an input value of the input filter bits of the input data IDTK, such that at least one switch element is turned off in each of the first string portions of the memory strings MS1_K and MSm_K. Correspondingly, each of the string current signals IS1_K and ISm_K has the current level IL0.

On the other hand, when the store value of the stored filter bits is equal to the input value of the input filter bits, the second string portion compares the stored computing bits and the input computing bits. When a similarity between the store value of the stored computing bits and the input value of the input computing bits is higher, a current level of the corresponding string current signal is higher. When the similarity between the store value of the stored computing bits and the input value of the input computing bits is lower, a current level of the corresponding string current signal is lower.

For example, in the embodiment shown in FIG. 5B, a store value of the stored filter bits of the first string portions of the memory string MS2_1 is equal to the input value of the input filter bits of the input data IDT1, such that each of the switch element of the first string portion of the memory string MS2_1 is turned on. At this moment, a current level of the string current signal IS2_1 is proportional to a similarity between a store value of the stored computing bits of the second string portion of the memory string MS2_1 and the input value of the input computing bits of the input data IDT1. Alternatively stated, when a difference between the store value of the stored computing bits of the second string portion of the memory string MS2_1 and the input value of the input computing bits of the input data IDT1 is smaller, the current level of the string current signal IS2_1 is larger.

Similarly, a store value of the stored filter bits of the first string portions of the memory string MS2_2 is equal to the input value of the input filter bits of the input data IDT2, such that each of the switch element of the first string portion of the memory string MS2_2 is turned on. At this moment, a current level of the string current signal IS2_2 is proportional to a similarity between a store value of the stored computing bits of the second string portion of the memory string MS2_2 and the input value of the input computing bits of the input data IDT2. Alternatively stated, when a difference between the store value of the stored computing bits of the second string portion of the memory string MS2_2 and the input value of the input computing bits of the input data IDT2 is smaller, the current level of the string current signal IS2_2 is larger.

Similarly, a store value of the stored filter bits of the first string portions of the memory string MS2_K is equal to the input value of the input filter bits of the input data IDTK, such that each of the switch element of the first string portion of the memory string MS2_K is turned on. At this moment, a current level of the string current signal IS2_K is proportional to a similarity between a store value of the stored computing bits of the second string portion of the memory string MS2_K and the input value of the input computing bits of the input data IDTK. Alternatively stated, when a difference between the store value of the stored computing bits of the second string portion of the memory string MS2_K and the input value of the input computing bits of the input data IDTK is smaller, the current level of the string current signal IS2_K is larger.

Referring to FIG. 5B and FIG. 1A to FIG. 1F, in some embodiments, in response to the stored computing bits of the memory string MS2_1 having the store value 4 and the input computing bits of the input data IDT1 having the input value 1, the string current signal IS2_1 has the current level IL4. In response to the stored computing bits of the memory string MS2_2 having the store value 3 and the input computing bits of the input data IDT2 having the input value 1, the string current signal IS2_2 has the current level IL3. In response to the stored computing bits of the memory string MS2_K having the store value 1 and the input computing bits of the input data IDTK having the input value 1, the string current signal IS2_K has the current level IL1.

In some embodiments, the memory cells in present disclosure are referred to as in-memory searching (IMS) cells. In various embodiments, the IMS cells can be implemented by floating gate memory, split-gate memory, silicon-oxide-nitride-oxide-silicon (SONOS) memory, floating dot memory, dynamic random-access memory (DRAM) and/or DRAM-like device (such as memory cells of 2T0C). In some embodiments, the IMS cells can also be implemented by emerging memory, such as ferroelectric field-effect transistor (FeFET).

In various embodiments, the memory device 510 and/or 100 can be implemented by various structures, such as two-dimensional (2D) flash structure or three-dimensional (3D) flash structure.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A memory device, comprising a memory string configured to generate a string current signal, the memory string comprising:
a first string portion configured to store at least one stored filter bit, and compare at least one input filter bit with the at least one stored filter bit; and
a second string portion coupled in series with the first string portion, and configured to store a plurality of stored computing bits, and compare a plurality of input computing bits with the plurality of stored computing bits,
wherein when an input value of the at least one input filter bit is different from a stored value of the at least one stored filter bit, the string current signal has a first current level,
when the input value of the at least one input filter bit is equal to the stored value of the at least one stored filter bit, and an input value of the plurality of input computing bits has a first difference with a stored value of the plurality of stored computing bits, the string current signal has a second current level, and
when the input value of the at least one input filter bit is equal to the stored value of the at least one stored filter bit, and the input value of the plurality of input computing bits has a second difference with the stored value of the plurality of stored computing bits, the string current signal has a third current level.

2. The memory device of claim 1, wherein each of the second current level and the third current level is larger than the first current level, and
the second current level and the third current level are different from each other.

3. The memory device of claim 2, wherein the first difference is smaller than the second difference, and
the second current level is larger than the third current level.

4. The memory device of claim 2, wherein when the input value of the at least one input filter bit is equal to the stored value of the at least one stored filter bit, and the input value of the plurality of input computing bits has a third difference with the stored value of the plurality of stored computing bits, the string current signal has a fourth current level,
the third difference is larger than each of the first difference and the second difference, and
the fourth current level is smaller than each of the second current level and the third current level.

5. The memory device of claim 4, wherein when the input value of the at least one input filter bit is equal to the stored value of the at least one stored filter bit, and the input value of the plurality of input computing bits has a fourth difference with the stored value of the plurality of stored computing bits, the string current signal has a fifth current level,
the fourth difference is larger than the first difference and the second difference, and
the fifth current level is smaller than the fourth current level, and is larger than the first current level.

6. The memory device of claim 1, wherein when the first string portion comprising a plurality of switch elements,
when the store value of the at least one stored filter bit has a range, each of the plurality of switch elements has a first threshold voltage level.

7. The memory device of claim 6, wherein
when the store value of the at least one stored filter bit has the range and the at least one input filter bit has a first input value, each of the plurality of switch elements is turned on, and
when the store value of the at least one stored filter bit has the range and the at least one input filter bit has a second input value different from the first input value, each of the plurality of switch elements is turned on.

8. The memory device of claim 6, wherein the plurality of switch elements are configured to receive a plurality of word line signals, respectively,
when the input value of the at least one input filter bit has the range, each of the plurality of word line signals has a first voltage level, and each of the plurality of switch elements is turned on.

9. A memory device, comprising a memory string configured to generate a string current signal, the memory string comprising:
a first string portion comprising a plurality of first switch elements, and configured to store at least one stored filter bit; and
a second string portion comprising a plurality of second switch elements coupled in series with the plurality of first switch elements, and configured to store a plurality of stored computing bits,
wherein the plurality of first switch elements are configured to respectively receive a plurality of first word line signals carrying at least one input filter bit,
the plurality of second switch elements are configured to respectively receive a plurality of second word line signals carrying a plurality of input computing bits,
when an input value of the at least one input filter bit is different from a stored value of the at least one stored filter bit, at least one of the plurality of first switch elements is turned off,
when the input value of the at least one input filter bit is equal to the stored value of the at least one stored filter bit, and an input value of the plurality of input computing bits has a first difference with a stored value of the plurality of stored computing bits, the string current signal has a first current level, and
when the input value of the at least one input filter bit is equal to the stored value of the at least one stored filter bit, and the input value of the plurality of input computing bits has a second difference with the stored value of the plurality of stored computing bits, the string current signal has a second current level.

10. The memory device of claim 9, wherein when the input value of the at least one input filter bit is equal to the stored value of the at least one stored filter bit, each of the plurality of first switch elements is turned on.

11. The memory device of claim 9, wherein the first difference is smaller than the second difference, and
the first current level is larger than the second current level.

12. The memory device of claim 9, wherein the plurality of second switch elements comprise:
a third switch element configured to have a first threshold voltage level when the plurality of stored computing bits has a first store value, and configured to have a second threshold voltage level larger than the first threshold voltage level when the plurality of stored computing bits has a second store value.

13. The memory device of claim 12, wherein the plurality of second switch elements further comprise:
a fourth switch element configured to have the first threshold voltage level when the plurality of stored computing bits has the second store value, and configured to have the second threshold voltage level when the plurality of stored computing bits has a third store value,
wherein the third store value is larger than each of the second store value and the first store value.

14. The memory device of claim 13, wherein the plurality of second switch elements further comprise:
a fifth switch element configured to have the first threshold voltage level when the plurality of stored computing bits has the third store value, and configured to have the second threshold voltage level when the plurality of stored computing bits has a fourth store value,
wherein the fourth store value is larger than the third store value.

15. The memory device of claim 13, wherein the plurality of second switch elements further comprise:
a fifth switch element configured to have the second threshold voltage level when the plurality of stored computing bits has the first store value, configured to have the first threshold voltage level when the plurality of stored computing bits has the second store value, and configured to have the first threshold voltage level when the plurality of stored computing bits has the third store value.

16. The memory device of claim 15, wherein the plurality of second switch elements further comprise:
a sixth switch element configured to have the second threshold voltage level when the plurality of stored computing bits has the first store value, configured to have the second threshold voltage level when the plurality of stored computing bits has the second store value, and configured to have the first threshold voltage level when the plurality of stored computing bits has the third store value.

17. A memory system, comprising a plurality of memory strings configured to generate a plurality of bit line signals, the plurality of memory strings comprising:
a plurality of first memory strings configured to compare a plurality of first stored data and a plurality of input data to generate a plurality of first string current signals, and sum the plurality of first string current signals to generate a first bit line signal; and
a plurality of second memory strings configured to compare a plurality of second stored data and the plurality of input data to generate a plurality of second string current signals, and sum the plurality of second string current signals to generate a second bit line signal,
wherein in response to a store value of store filter bits stored in a third memory string of the plurality of first memory strings being different from an input value of input filter bits of a first input data of the plurality of input data, at least one switch element in the third memory string is turned off, and
in response to a store value of store filter bits stored in a fourth memory string of the plurality of second memory strings being equal to the input value of the input filter bits of the first input data of the plurality of input data, when a difference between a store value of stored computing bits stored in the fourth memory string and an input value of input computing bits of the first input data is smaller, a current level of a third string current signal generated by the fourth memory string is larger.

18. The memory system of claim 17, wherein in response to a store value of store filter bits stored in a fifth memory string of the plurality of first memory strings being different from an input value of input filter bits of a second input data of the plurality of input data, at least one switch element in the fifth memory string is turned off.

19. The memory system of claim 18, wherein in response to a store value of store filter bits stored in a sixth memory string of the plurality of second memory strings being equal to the input value of the input filter bits of the second input data of the plurality of input data, when a difference between a store value of stored computing bits stored in the sixth memory string and an input value of input computing bits of the second input data is smaller, a current level of a fourth string current signal generated by the sixth memory string is larger.

20. The memory system of claim 19, wherein in response to a first difference being between the store value of the stored computing bits stored in the fourth memory string and the input value of the input computing bits of the first input data, the third string current signal has a first current level,
in response to a second difference being between the store value of the stored computing bits stored in the sixth memory string and the input value of the input computing bits of the second input data, the fourth string current signal has a second current level,
the first difference is larger than the second difference, and
the first current level is smaller than the second current level.
